(19) United States
(12) Patent Application Publication
(10) Pub. No.: US 2010/0328863 A1
(43) Pub. Date: Dec. 30, 2010

(54) ELECTRONIC APPARATUS

(75) Inventor: Naoya SHIGENOBU, Oume-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/793,585

(22) Filed: Jun. 3, 2010

(30) Foreign Application Priority Data
Jun. 30, 2009 (JP) 2009-155379

(51) Int. Cl. H05K 7/00

(52) U.S. Cl. 361/679.01

(57) ABSTRACT

According to an aspect of the present invention, there is provided an electronic apparatus including: a housing having: a first surface; and a second surface having a height different from that of the first surface in a direction perpendicular to the first surface, the second surface having a penetrating hole formed therein; and a film having: a first region to be faced to the first surface of the housing; and a second region to be faced to the second surface of the housing, the second region having a wall thickness larger than that of the first region.

### CROSS-REFERENCE TO RELATED APPLICATIONS

This application is based upon and claims the benefit of priority from Japanese Patent Application No. 2009-155379, filed on Jun. 30, 2009, the entire contents of which are incorporated herein by reference.

### BACKGROUND

1. Field

An aspect of the present invention relates to an electronic apparatus.

2. Description of the Related Art

To stick a sheet-shaped film or the like, a technique for preventing an air bubble from being entered between a base member for the sticking (onto which the film or the like is to be stuck) and the film has come into wide use. JP-H10-105067-A, for example, discloses a technique to reliably vent air involved in sticking an information label to the stick-base position of a cabinet, thereby preventing the information label from partly swelling due to the enclosed air.

In the prior-art technique, however, consideration has not been given to the sticking of a sticking-subject film to a stick-base having a rugged surface. When the film is stuck to the stick-base member having a rugged surface, air bubbles will intrude into the rugged steps to lower a bonding power.

### BRIEF DESCRIPTION OF THE DRAWINGS

A general architecture that implements the various feature of the present invention will now be described with reference to the drawings. The drawings and the associated descriptions are provided to illustrate embodiments of the present invention and not to limit the scope of the present invention.

FIG. 1 exemplarily illustrates a portable computer according to a first embodiment.

FIG. 2 illustrates a rear view of a display unit in the portable computer shown in FIG. 1.

FIG. 3 illustrates a sectional view taken along a line F3-F3 in the display unit shown in FIG. 2.

FIG. 4 illustrates an enlarged sectional view of a first part enclosed with F4, in the display unit shown in FIG. 3.

FIG. 5 illustrates a first case in this embodiment before decoration.

FIG. 6 illustrates an enlarged sectional view of a second part enclosed with F5, in the first case 23 before the decoration as shown in FIG. 5.

FIG. 7 exemplarily illustrates a first modification to the portable computer according to this embodiment.

FIG. 8 exemplarily illustrates a second modification to the portable computer according to this embodiment.

FIG. 9 exemplarily illustrates a third modification to the portable computer according to this embodiment.

FIG. 10 exemplarily illustrates an apparatus for the vacuum thermal transfer of the first case in this embodiment.

FIG. 11 illustrates a sectional view of a display unit in a second embodiment.

FIG. 12 illustrates an enlarged sectional view of a part of the display unit in the second embodiment.

### DETAILED DESCRIPTION

Various embodiments according to the present invention will be described hereinafter with reference to the accompanying drawings. In general, according to one embodiment of the present invention, there is provided an electronic apparatus including: a housing having: a first surface; and a second surface having a height different from that of the first surface in a direction perpendicular to the first surface, the second surface having a penetrating hole formed therein; and a film having: a first region to be faced to the first surface of the housing; and a second region to be faced to the second surface of the housing, the second region having a wall thickness larger than that of the first region.

Now, a first embodiment will be described with reference to the drawings. Here in this specification, this side (that is, the side of a user) shall be defined as a “front direction”, a deeper side viewed from the user as a “rear direction”, a left side viewed from the user as a “left direction”, a right side viewed from the user as a “right direction”, an upper direction viewed from the user as an “upper direction”, and a lower direction viewed from the user as a “lower direction”.

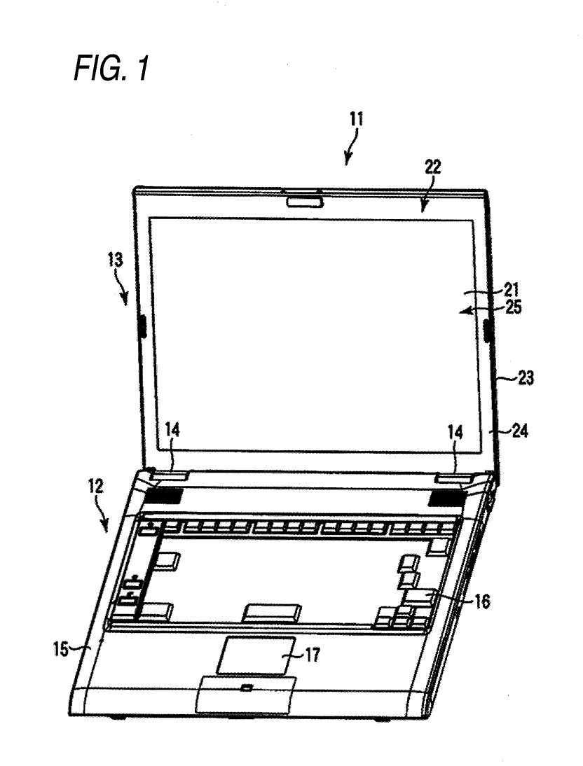

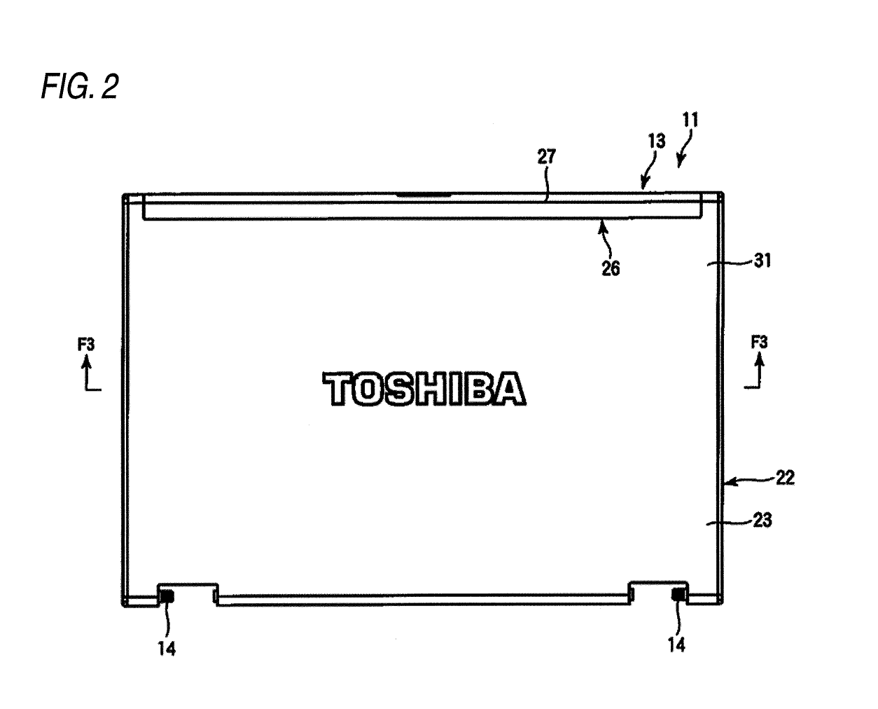

The configuration of the electronic apparatus according to this embodiment will be described with reference to FIGS. 1 and 2. FIG. 1 is illustrates the appearance of a portable computer 11 as an example of the electronic apparatus. FIG. 2 illustrates a rear view of a display unit in the portable computer shown in FIG. 1.

As shown in FIG. 1, the portable computer 11 includes a body unit 12, a display unit 13, and hinge portions 14 which are disposed between the body unit 12 and the display unit 13. The hinge portions 14 rotatably support the display unit 13.

As shown in FIG. 1, the body unit 12 includes a body cabinet 15 which forms the outer shell of this body unit, a keyboard 16 and a touch pad 17 which are mounted on the upper surface of the body cabinet 15, and a printed circuit board(not shown) which is accommodated inside the body cabinet 15.

The display unit 13 can be rotated between a first position where the display unit 13 it erects relative to the body unit 12 as shown in FIG. 1, and a second position where it lies on the body unit 12 so as to become parallel to this body unit.

As shown in FIGS. 1 and 2, the display unit 13 includes a liquid-crystal display 21 which is an example of a display, and a housing 22 which is made of a synthetic resin and which surrounds the periphery of the liquid-crystal display 21. The housing 22 includes a first case 23 (cover) which covers the rear surface of the liquid-crystal display 21, and a second case (mask). The second case 24 has a square opening 25 at a center thereof to expose the liquid-crystal display 21 therethrough.

As shown in FIG. 2, the first case 23 has a notch 26 at its end opposite to its end at which the hinge portions 14 are provided. This first case 23 further has a cover member 27 which covers the notch 26.

The portable computer 11 includes an exterior decoration on the first case 23 in order to enhance a fine view. The exterior decoration is formed by sticking, for example, a film or a transfer foil onto the first case 23.

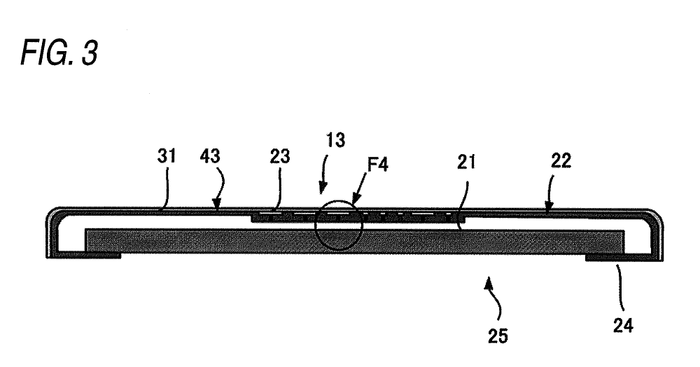

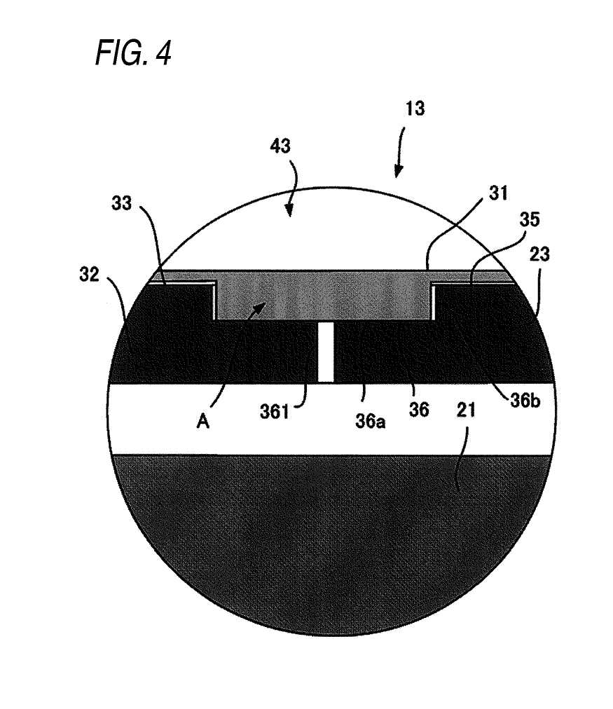

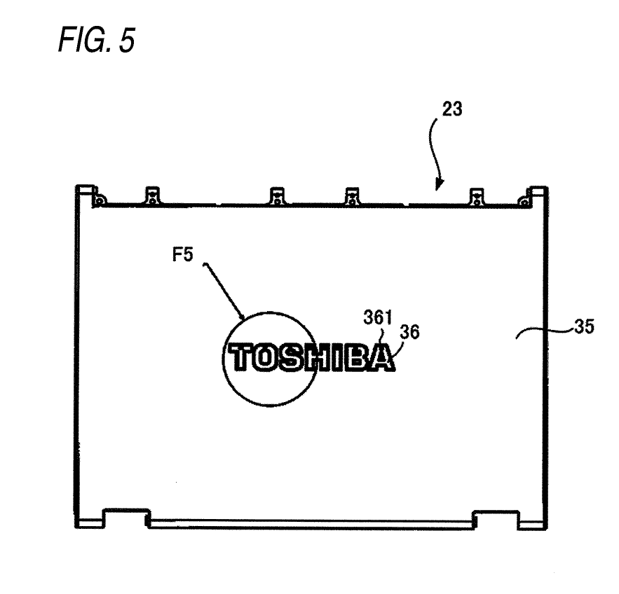

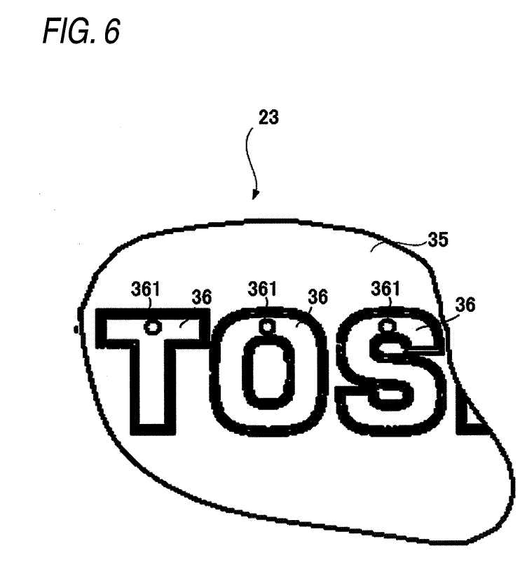

The decoration in the portable computer 11 of this embodiment will be described in detail with reference to FIGS. 3 through 6. FIG. 3 illustrates a sectional view taken along a line F3-F3 in the display unit shown in FIG. 2. FIG. 4 illustrates a sectional view enlargedly showing a first part enclosed with F4 in the display unit shown in FIG. 3. FIG. 5 illustrates a view showing the first case 23 before the decoration in this embodiment. FIG. 6 illustrates a sectional view enlargedly showing a second part enclosed with F5 in the first case 23 before the decoration as shown in FIG. 5.

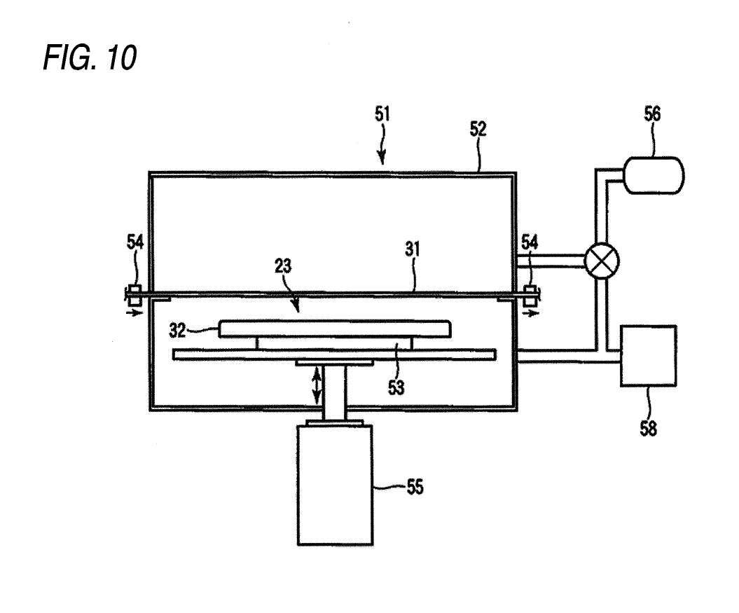

As shown in FIGS. 3 and 4, the portable computer 11 of this embodiment includes an emphasis region A which is emphasized in design with letters, a mark, a symbol or the like by sticking the film, the transfer foil or the like onto the first case 23. In this embodiment, the emphasis region A has a wall thickness larger than in the other region. In this embodiment, the expression “wall thickness” denotes the dimensional width of a member in the thickness direction thereof. A case where the decorating film has been stuck onto the first case 23 by a vacuum thermal transfer technique, will be exemplified below. And, the vacuum thermal transfer technique will be stated later with reference to FIG. 10.

As shown in FIGS. 3 and 4, the first case 23 includes the decorating film 31, and a base member 32 onto which the decorating film 31 is stuck. The decorating film 31 is bonded onto the base member 32 by the vacuum thermal transfer. The base member 32 contains a stick-base region 33 for sticking the decorating film 31 thereonto.

As shown in FIGS. 3 and 4, the stick-base region 33 includes an outer face 35 which confronts the outside, and an recess 36 which is depressed toward the interior of the housing as viewed from the outer face 35. The recess 36 has a bottom wall 36a, and a peripheral wall 36b which extends over the bottom wall 36a and the outer face 35.

As shown in FIG. 4, the recess 36 is formed to face the emphasis region A of the decorating film 31 and accommodates at least part of the emphasis region A. Thus, the tolerance between the emphasis region A and the first case 23 in the other region having a wall thickness smaller than that of the emphasis region A can be absorbed. When the film, the transfer foil or the like is partly thickened to emphasize design, such as the letters, the mark and the symbol, air might be entered into around a boundary where the wall thickness is changed. In this embodiment, since at least part of the emphasis region A is accommodated in the recess 36, the tolerance between the respective regions of the first case 23 and the film 31 can be absorbed.

Owing to such a configuration, a gas is suppressed from being contained between the sticking-subject member (the decorating film, the transfer foil or the like) and the stick-base member (the cabinet or the like, onto which the decorating film or the like is to be stuck) around the boundary where the wall thickness is changed. Thus, the bonding power between the sticking-subject member and the stick-base member.

As shown in FIGS. 4 through 6, in the bottom wall 36a of the recess 36, a penetrating hole 361 is provided at a position corresponding to the emphasis region A of the decorating film 31.

In a case where the surface of the stick-base member (the cabinet or the like) onto which the sticking-subject member (the decorating film, the transfer foil or the like) is to be stuck has a rugged surface, when sticking, a gas might be contained therebetween in a direction intersecting with the surfaces thereof. By providing an air vent hole for debubbling is provided in the stick-base member (especially, at a concave region in the rugged surface), the gas entered between the sticking-subject member and the stick-base member can be vented. Thus, the bonding power between the sticking-subject member and the stick-base member is enhanced. In the portable computer 11 of this embodiment, the penetrating hole 361 is provided to vent the air having intruded between the emphasis region A of the decorating film 31 and the recess 36 therethrough.

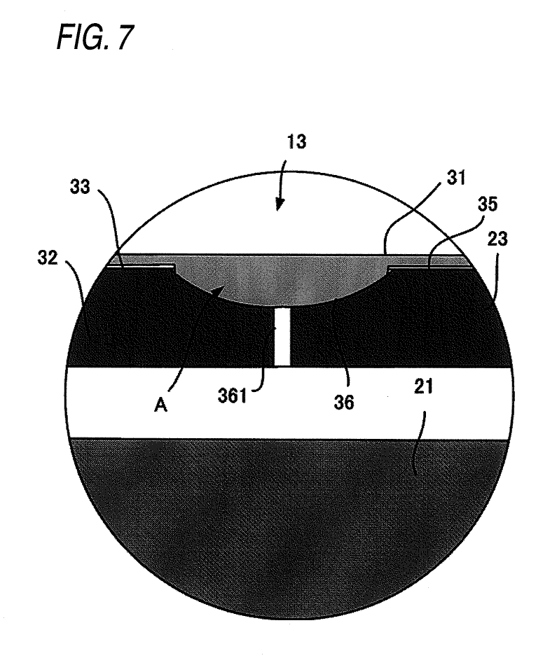

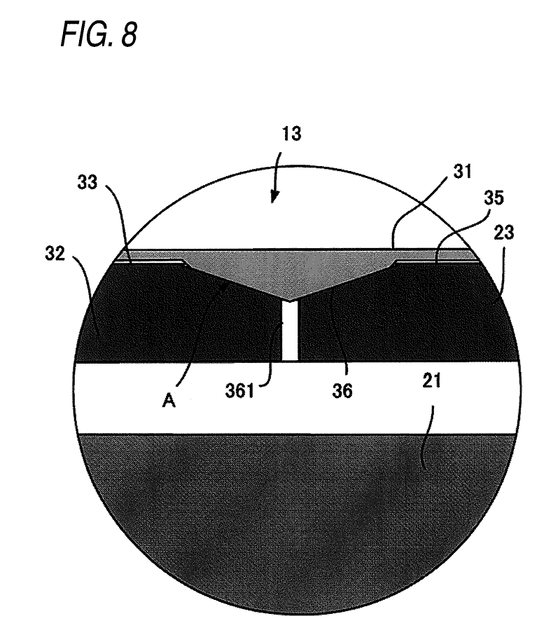

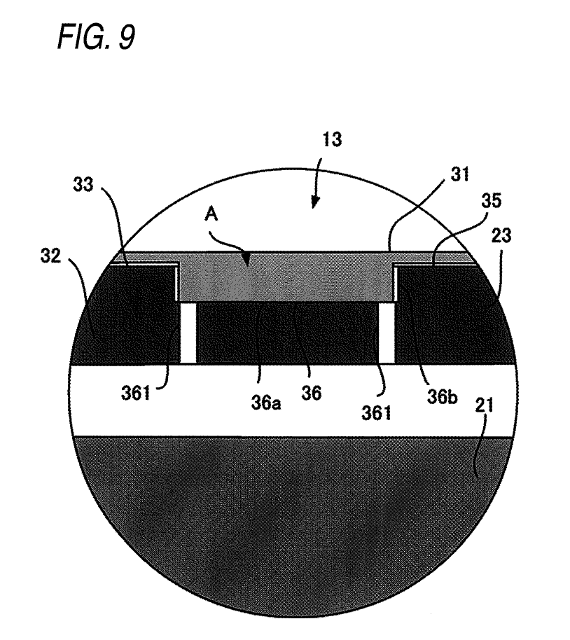

Next, modifications to the portable computer 11 according to the embodiment of the present invention will be described with reference to FIGS. 7 through 9. FIG. 7 exemplarily illustrates the first modification to the portable computer 11 according to this embodiment. FIG. 8 exemplarily illustrates the second modification to the portable computer 11 according to this embodiment. FIG. 9 exemplarily illustrates the third modification to the portable computer 11 according to this embodiment. In the first through third modifications, configurations which have functions identical or similar to those of the portable computer 100 according to the first embodiment will be assigned the same numerals and signs, which shall be omitted from description. In the first through third modifications, the shapes of the recesses 36 or the penetrating holes 361 are different from those in the first embodiment, respectively. The portable computer 11 in each of the first through third modifications presents substantially the same appearance as shown in FIG. 1.

The housing 22 of the portable computer 11 in each of the first through third modifications has the outer face 35, and the recess 36 which is depressed toward the interior of the housing as viewed from the outer face 35, as the stick-base region 33 for sticking the decorating film 31 thereonto.

First, the first modification in this embodiment will be described with reference to FIG. 7. As shown in FIG. 7, in the first modification to the portable computer 11, the recess 36 has a circular arc sectional shape. In the recess 36, the penetrating hole 361 is provided at the position being the most distant from the outer face 35. Owing to such a configuration, air having intruded between the emphasis region A of the decorating film 31 and the recess 36 can be efficiently vented through the penetrating hole 361. In this modification, the recess 36 does not have any abrupt corner extending between the bottom wall 36a and the peripheral wall 36b, so that an outer surface inside the recess 36 and the decorating film 31 can be held in contact under uniformed pressures. Accordingly, a close adhesion characteristic can be enhanced more than the configuration of the portable computer 11 shown in FIGS. 1 through 6.

Next, the second modification in this embodiment will be described with reference to FIG. 8. As shown in FIG. 8, in the second modification to the portable computer 11, the recess 36 is formed by conically depressing the outer face 35 to have a triangular sectional shape. In the same manner as in the first modification, the penetrating hole 361 is provided at the position in the recess 36 being the most distant from the outer face 35. Owing to such a configuration, the same advantage as in the first modification can be obtained.

Next, the third modification in this embodiment will be described with reference to FIG. 9. As shown in FIG. 9, the recess 36 in the third modification has the same shape as that of the recess 36 of the portable computer 11 shown in FIGS. 1 through 6. More specifically, the recess 36 in the third modification includes the bottom wall 36a, the peripheral wall 36b, and a corner portion 36c which extends between the bottom wall 36a and the peripheral wall 36b.

In the third modification in this embodiment, the penetrating hole 361 is provided in the corner portion 36c. Owing to such a configuration, air entered between the corner portion 36c and the decorating film 31 can be efficiently vented, and the same advantage as that of the first modification can be obtained.

As stated above, any of the first through third modifications in this embodiment is properly used in conformity with the shape of the emphasis region A of the decorating film 31, thereby effectively venting the gas entered between the sticking-subject member (the decorating film, the transfer foil or the like) and the stick-base member (the cabinet or the like), and enhancing the bonding power between the sticking-subject member the stick-base member. For example, the first modification can be employed for the decorating film, the transfer foil or the like whose emphasis region A is thickened to have a semispherical sectional shape, the second modification can be employed for the decorating film, the transfer foil or the like whose emphasis region A is thickened to have a conical sectional shape, and the third modification can be employed for the decorating film, the transfer foil or the like whose emphasis region A is thickened to have a rectangular sectional shape.

Next, a method for manufacturing the first case 23 in this embodiment will be described with reference to FIG. 10. FIG. 10 exemplarily illustrates an apparatus for the vacuum thermal transfer of the first case in this embodiment. In this embodiment, the vacuum thermal transfer is employed for sticking the decorating film 31 onto the base member 32. As shown in FIG. 10, the base member 32 is set on a setting table 53 within the vacuum chamber 52. The decorating film 31 is stretched over the base member 32. Thus, the interior of the vacuum chamber 52 is divided into the two regions of a region on the upside of the decorating film 31 and a region on the downside of the decorating film 31. In this state, a vacuum pump 58 is driven to bring the interior of the vacuum chamber 52 into a vacuum state, and the decorating film 31 is heated by heaters 54.

Besides, a cylinder 55 is driven so as to lift the setting table 53 and to bring the base member 32 into contact with the decorating film 31. On this occasion, the decorating film 31 and the base member 32 are sometimes bonded while the air is involved therebetween. In this embodiment, however, the air between the film 31 and the base member 32 can be vented through the penetrating hole 36 as stated above.

In addition, air is fed from an air tank 56 into the region on the upside of the decorating film 31 within the vacuum chamber 52, thereby to release the vacuum of this place back to a pressure to a level of the atmospheric pressure. Then, the surface of the base member 32 is covered with the decorating film 31 by the atmospheric pressure. In this way, the vacuum thermal transfer is completed.

According to this embodiment, the air between the film 31 and the base member 32 can be vented through the penetrating hole 36, and the bonding power between the decorating film 31 and the base member 32 can be enhanced. Thus, the inferior bonding between the decorating film 31 and the base member 32 can be relieved, and a product yield in the manufacture of the first case 23 can be enhanced.

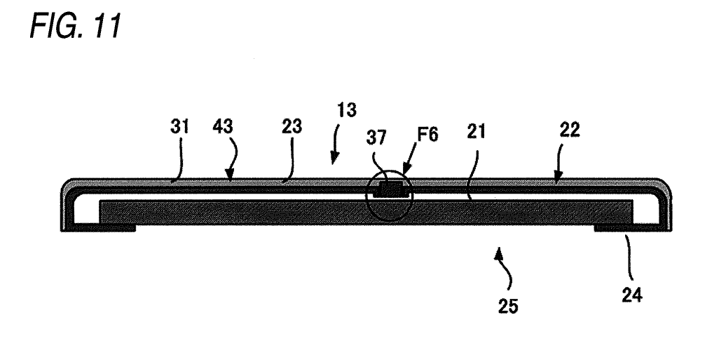

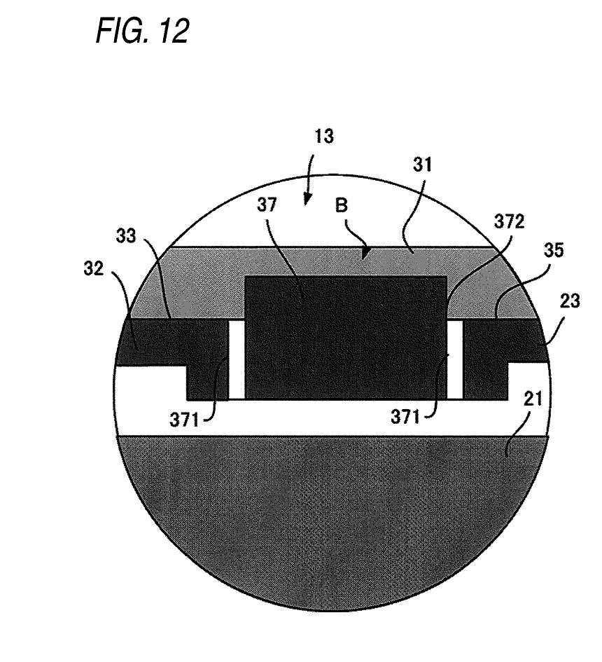

Next, a second embodiment of the electronic apparatus will be described with reference to FIGS. 11 and 12. FIG. 11 illustrates a sectional view of a display unit in the second embodiment. FIG. 12 illustrates a sectional view enlargedly showing a first part enclosed with F6 in the display unit in the second embodiment.

A portable computer 11 according to the second embodiment is different in the shape of a stick-base region 33 and the position of a penetrating hole 36 from that of the first embodiment, but it is common to the first embodiment in the other portions. Therefore, the different portions will be chiefly described, and the common portions shall be omitted from description by assigning common numerals. The portable computer presents an appearance similar to that of the first embodiment shown in FIG. 1.

As shown in FIGS. 11 and 12, in th the portable computer 11 of the second embodiment, a protrusion 37 outwardly protruding (protruding in a direction opposite to the interior of a housing 11) from the outer face 35 of a first case 23 is provided. In the second embodiment, a region B which opposes to the protrusion 37 in a decorating film 31 has a wall thickness smaller than in the other region.

In the second embodiment, the peripheral edge part of the protrusion 37 of the outer face 35 of the first case 23 has penetrating holes 371. The peripheral edge part of the protrusion 37 is, for example, a corner 372 positioned between the outer face 35 and the protrusion 37.

In this manner, according to this embodiment, the air between the film 31 and a base member 32 can be vented through the penetrating holes 371, and the bonding power between the decorating film 31 and the base member 32 can be enhanced. Thus, the inferior bonding between the decorating film 31 and the base member 32 can be relieved, and a product yield in the manufacture of the first case 23 can be enhanced.

The electronic apparatus is not limited to the use for the portable computer 11 as indicated the above embodiments, but the invention can also be performed for another electronic apparatus, such as a mobile phone. Although the vacuum thermal transfer has been exemplified as the bonding method for the decorating film 31, the invention is not restricted thereto, and the decorating film 31 may be bonded onto the base member 32 by in-mold molding such as IMD (In Mold Design), IMR (In Mold Roll) or IML (In Mold Label).

Further, the embodiments indicate the example in which the decorating film 31 is applied to the first case 23 covering the rear of the liquid-crystal display 21. However, the invention is not restricted thereto. The decorating film 31 may be applied to, for example, the body unit 12, or the second case 24 of the display unit 13.

Of course, the various modifications can be performed within a scope not departing from the spirit of the invention.

An aspect of the present invention provides the electronic apparatus in which the bonding power of the film is enhanced.

What is claimed is:

1. An electronic apparatus comprising:
a housing comprising:
a first surface; and
a second surface having a second height different from a first height of the first surface in a direction perpendicular to the first surface, the second surface comprising a hole; and
a film comprising:
a first region configured to face the first surface of the housing; and
a second region configured to face the second surface of the housing, the second region comprising a second wall thicker than a first wall of the first region.

2. The apparatus of claim 1,
wherein the first surface comprises a recess region on the housing,
wherein the second surface comprises at least a portion of the recess region, and
wherein the hole in the second surface is in a direction perpendicular to the first surface of the housing.

3. The apparatus of claim 2,
wherein the first surface of the housing is at an exterior face of the housing; and
wherein the recess region is depressed from the exterior face.

4. The apparatus of claim 3,
wherein the housing further comprises a wall portion between the first surface and a peripheral edge of the second surface along the direction perpendicular to the first surface.

5. The apparatus of claim 4,
wherein the hole in the second surface is at a position substantially distant from the wall portion.

6. The apparatus of claim 5,
wherein the recess region of the second surface is depressed inwardly from the first surface and comprising a height shorter than the first height, and
wherein the hole is within the recess region.

7. The apparatus of claim 6,
wherein the hole is perpendicular to a peripheral edge of the hole.

8. The apparatus of claim 7,
wherein the housing further comprises a corner portion comprising by the wall portion and the second surface,
wherein the hole is in the corner portion.

9. The apparatus of claim 1,
wherein the second surface comprises a protrusion from the housing,
wherein the first surface comprises at least a portion of the protrusion, and
wherein the hole is in the second surface in a direction perpendicular to the second surface.

10. The apparatus of claim 9,
wherein the housing further comprises a wall portion between the first surface and a peripheral edge of the second surface along the direction perpendicular to the second surface,
wherein the housing further comprises a corner portion comprising the wall portion and the first surface, and
wherein the hole is in the corner portion.
